(19) United States
(12) Patent Application Publication
(10) Pub. No.: US 2026/0123318 A1
(43) Pub. Date: Apr. 30, 2026

(54) SUBSTRATE STRUCTURE FABRICATING METHOD

(71) Applicant: Samsung Electronics Co., Ltd., Suwon-si (KR)

(72) Inventors: Taeseong Kim, Suwon-si (KR); Jaehyun Phee, Suwon-si (KR); Jaehee Nam, Suwon-si (KR); Dongyub Yee, Suwon-si (KR); Hojin Lee, Suwon-si (KR); Dongchan Lim, Suwon-si (KR); Joohee Jang, Suwon-si (KR); Sonkwan Hwang, Suwon-si (KR)

(21) Appl. No.: 19/370,926

(22) Filed: Oct. 28, 2025

(30) Foreign Application Priority Data
Oct. 31, 2024 (KR) 10-2024-0152968

(51) Int. Cl. H01L 21/304; H01L 21/268; H01L 23/00; H10D 88/00

(52) U.S. Cl. CPC H10P 52/00; H10D 88/01; H10P 34/42; H10W 90/792

(57) ABSTRACT

Provided are methods of manufacturing including preparing a first substrate including a first surface and a second surface opposite the first surface, wherein the first substrate includes a device region and an edge region surrounding the device region, forming a first insulating layer on the first surface of the first substrate, the first substrate and the first insulating layer forming a first wafer, forming a stepped portion in an upper surface of the first insulating layer so that a first vertical level of a first portion of the upper surface of the first insulating layer in the device region is different from a second vertical level of a second portion of the upper surface of the first insulating layer in the edge region, bonding the first wafer to a second wafer, and separating the edge region from the device region of the first substrate by emitting a laser beam onto the second surface of the first substrate.

### CROSS-REFERENCE TO RELATED APPLICATION

This U.S. non-provisional application is based on and claims priority under 35 U.S.C. Korean Patent Application No. 10-2024-0152968, filed on Oct. 31, 2024, in the Korean Intellectual Property Office, the disclosure of which is incorporated by reference herein in its entirety.

### BACKGROUND

The inventive concept relates to a substrate structure fabricating method, and more particularly, to a method of trimming an edge of a substrate.

A wafer trimming process may be performed to protect a wafer during subsequent processes. Typical trimming devices apply mechanical forces during a process and may cause chipping, in which defects or byproducts form on a surface of a wafer due to physical stress on the wafer. Accordingly, research is being conducted on a method of effectively performing wafer trimming.

### SUMMARY

The inventive concept relates to a substrate structure fabricating method capable of effectively trimming wafers to improve process reliability and efficiency.

Also, the objects of the inventive concept are not limited to the aforementioned object, but other objects not described herein will be clearly understood by those skilled in the art from the following description.

According to an aspect of the inventive concept, there is provided a method of manufacturing including preparing a first substrate including a first surface and a second surface opposite the first surface, wherein the first substrate includes a device region and an edge region surrounding the device region, forming a first insulating layer on the first surface of the first substrate, the first insulating layer having a lower surface adjacent to the first surface of the first substrate, and an upper surface opposite the lower surface, the first substrate and the first insulating layer forming a first wafer; forming a stepped portion in the upper surface of the first insulating layer so that a first vertical level of a first portion of the upper surface of the first insulating layer in the device region is different from a second vertical level of a second portion of the upper surface of the first insulating layer in the edge region, bonding the first wafer to a second wafer, and separating the edge region from the device region of the first substrate by emitting a laser beam onto the second surface of the first substrate.

According to another aspect of the inventive concept, there is provided a method of manufacturing including preparing a first substrate including a first surface and a second surface opposite the first surface, wherein the first substrate includes a device region and an edge region surrounding the device region, forming a first trench surrounding the device region, in the first surface of the first substrate, forming a first circuit layer and a first insulating layer surrounding the first circuit layer, on the first substrate in which the first trench is formed, the first substrate and the first insulating layer forming a first wafer, bonding the first wafer to a second wafer so that the first insulating layer and a second insulating layer of the second wafer are adjacent to each other, and separating the edge region from the device region of the first substrate by emitting a laser beam onto the second surface of the first substrate.

According to another aspect of the inventive concept, there is provided a method of manufacturing including preparing a first substrate including a first surface and a second surface opposite the first surface, wherein the first substrate includes a device region and an edge region surrounding the device region, forming a first circuit layer and a first insulating layer surrounding the first circuit layer, on the first substrate, the first insulating layer having a lower surface adjacent to the first surface of the first substrate, and an upper surface opposite the lower surface, the first substrate and the first insulating layer forming a first wafer, forming a stepped portion in the upper surface of the first insulating layer, bonding the first wafer to a second wafer so that the first insulating layer and a second insulating layer of the second wafer are adjacent to each other, and separating the edge region from the device region of the first substrate by emitting a laser beam onto the second surface of the first substrate.

According to another aspect of the inventive concept, provided as substrate structures fabricated according to any of the methods provided herein.

### BRIEF DESCRIPTION OF THE DRAWINGS

Embodiments will be more clearly understood from the following detailed description taken in conjunction with the accompanying drawings in which:

FIGS. 1 and 2 are cross-sectional views of a substrate structure in an intermediate stage of processes and illustrate a substrate structure fabricating method, according to an embodiment;

FIGS. 3A and 3B are plan views of a substrate structure in an intermediate stage of processes and illustrate a substrate structure fabricating method, according to an embodiment;

FIG. 4 is a cross-sectional view of a substrate structure in an intermediate stage of processes and illustrates a substrate structure fabricating method, according to an embodiment;

FIG. 5 is an enlarged view of region A of FIG. 4;

FIG. 6 is a cross-sectional view of a substrate structure in an intermediate stage of processes and illustrates a substrate structure fabricating method, according to an embodiment;

FIG. 7 is an enlarged view of region B of FIG. 6;

FIG. 8 is a cross-sectional view of a substrate structure in an intermediate stage of processes and illustrates a substrate structure fabricating method, according to an embodiment;

FIGS. 9 to 12 are cross-sectional views of a substrate structure in an intermediate stage of processes and illustrate a substrate structure fabricating method, according to an embodiment; and

FIGS. 13 and 14 are cross-sectional views of a substrate structure in an intermediate stage of processes and illustrate a substrate structure fabricating method, according to an embodiment.

### DETAILED DESCRIPTION OF THE EMBODIMENTS

Hereinafter, embodiments are described in detail with reference to the accompanying drawings. The same reference numerals are given to the same elements in the drawings, and repeated descriptions thereof are omitted.

In the following embodiments, terms “first” and “second” are used to distinguish one component from another component, but the components should not be limited by these terms.

In the following embodiments, the singular forms include the plural forms as well, unless the context clearly indicates otherwise.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “lower,” “above,” “upper,” and the like, may be used herein for ease of description to describe positional relationships, such as illustrated in the figures, for example. It will be understood that the spatially relative terms encompass different orientations of the device in addition to the orientation depicted in the figures.

The term “substrate” may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.), or a stack structure including such a base substrate and layers formed on the base substrate.

The term “wafer” as used herein may include a plurality of dies, each die corresponding to a chip when cut from a wafer.

A method according to various embodiments may include preparing a first substrate 101 (or first base substrate) including a first surface 100a and a second surface 100b facing each other, wherein the first substrate 101 includes a device region CA and an edge region EA, forming a first insulating layer 110 on the first surface 100a of the first substrate 101, in which the first insulating layer 110 and the first substrate 101 form a first wafer 10 (along with a first wiring pattern 106 and a first device layer 104), forming a stepped portion in an upper surface of at least one of the first substrate 101 and the first insulating layer 110, bonding the first wafer 10 to a second wafer 20, and separating the edge region EA from the device region CA of the first substrate 101 by emitting a laser beam L onto the second surface of the first substrate 101.

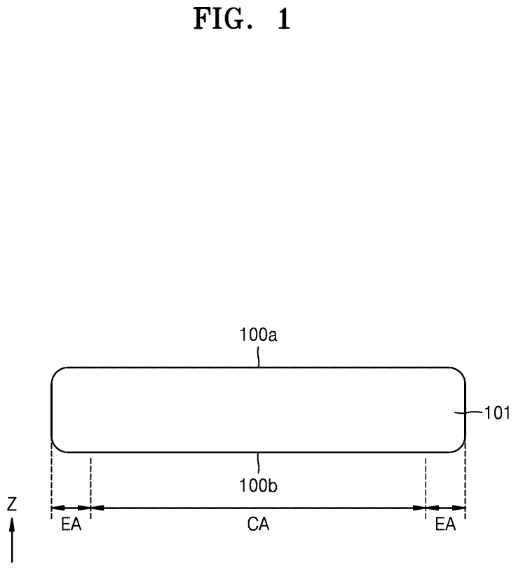

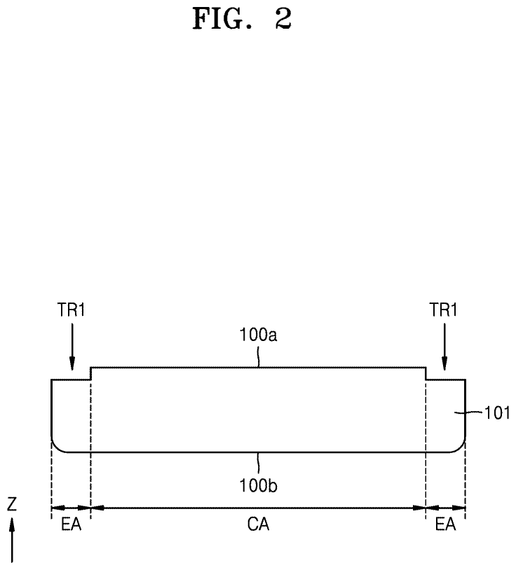

FIGS. 1 and 2 are cross-sectional views of a substrate structure in an intermediate stage of processes and illustrate a substrate structure fabricating method, according to an embodiment.

Referring to FIG. 1, a first substrate 101 including a first surface 100a and a second surface 100b facing each other may be prepared. The first substrate 101 may be a device region CA and an edge region EA. In an embodiment, the first substrate 101 may be a base substrate (an initial substrate), and the device region CA may be a region in which a plurality of device patterns are formed in and/or on the first substrate 101 (e.g., device patterns forming devices, such as transistors and logic gates formed of interconnected ones of such transistors). For example, a device pattern may be formed in and/or on the first surface 100a of the first substrate 101 in the device region CA. The edge region EA may surround the device region CA. The edge region EA may represent for example, a bevel edge of a wafer. As used herein, “in a device region” may be understood as “in a region overlapping the device region CA of the first substrate 101 in a vertical direction,” and “in an edge region” may be understood as “in a region overlapping the edge region EA of the first substrate 101 in the vertical direction.”

As used herein the terms “on”, “covers”, or “overlapping” or forms thereof, are intended to mean that an element is over or aside another element. The elements may be touching or not. For example, there may be layers between layers that are “on” one another. An element “on” or “covering” or “overlapping” another element need not cover an entire top surface of an element below to be considered “on” or “covers” or “overlapping”. The terms are intended to encompass one element “on” or “covers” or “overlapping” all, or any part of, an element below it. As used herein, the word “surrounds” is intended to mean that an element is outside the other element. The elements may be touching or not. The surrounding element may or may not completely surround an inner element.

The first substrate 101 may be a bulk semiconductor crystalline substrate, such as a bulk silicon or it may be a silicon-on-insulator (SOI). The first substrate 101 may be for example, a silicon substrate, or may be formed of other materials, such as, but not limited to, silicon germanium, silicon germanium on insulator (SGOI), indium antimonide, a lead telluride compound, indium arsenide, indium phosphide, gallium arsenide, or gallium antimonide.

Referring to FIG. 2, a stepped portion may be formed in the Z direction of the first surface 100a of the first substrate 101. According to some embodiments, a first trench TR1 may be formed in the first surface 100a of the first substrate 101, and thus, the first substrate 101 may have a stepped portion. The first trench TR1 may be located in the edge region EA of the first substrate 101. The first trench TR1 may be formed by etching at least a portion of the first substrate 101, which overlaps the edge region EA, in a direction from the first surface 100a to the second surface 100b (i.e., in a Z direction).

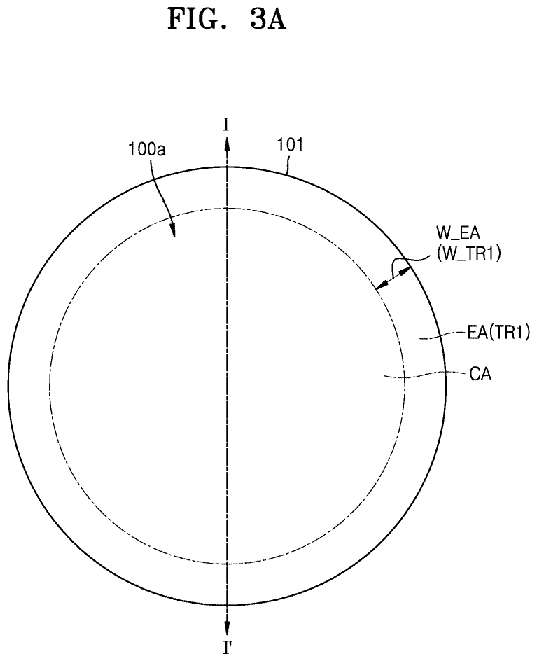

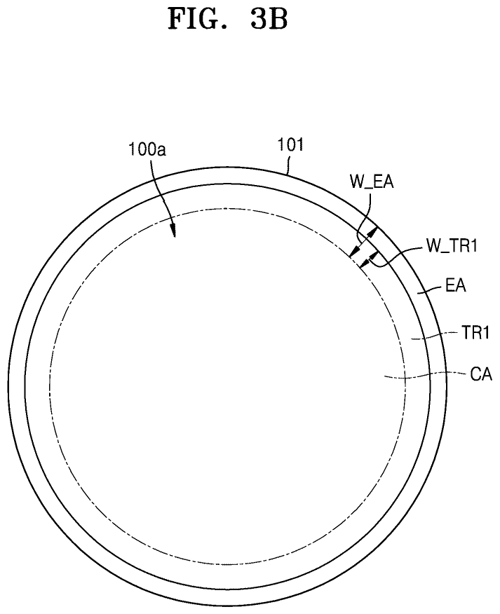

FIGS. 3A and 3B are plan views of a substrate structure in an intermediate stage of processes and illustrate a substrate structure fabricating method, according to an embodiment.

FIGS. 3A and 3B are plan views schematically illustrating positional relationships between the device region CA, the edge region EA, and the first trench TR1 of the first substrate 101. In an embodiment, a width W_EA of the edge region EA and a width W_TR1 of the first trench TR1 may each be in a range from about 0.5 mm to about 5 mm, or from about 1 mm to about 4 mm. In an embodiment, the width W_EA of the edge region EA and the width W_TR1 of the first trench TR1 may each be about 2 mm.

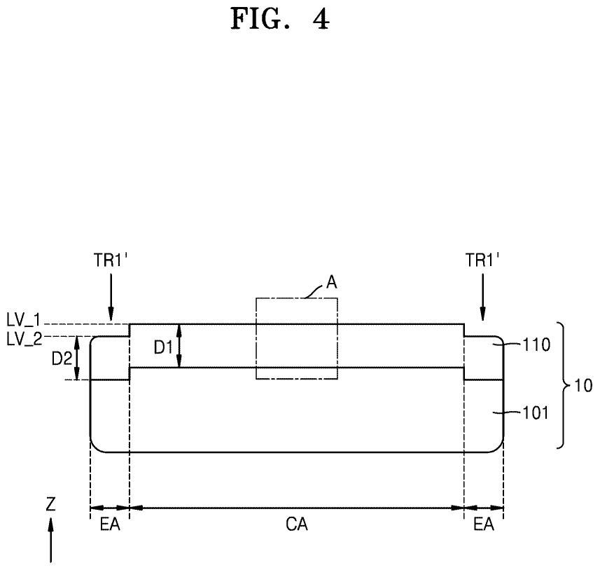

Referring to FIG. 3A, in a plan view, the first trench TR1 may surround the device region CA of the first substrate 101. In an embodiment, the width W_TR1 of the first trench TR1 may be equal to the width W_EA of the edge region EA. “EA(TR1)” refers to an area of the edge region EA and first trench region TR1. In this case, as shown in FIG. 2, the vertical level of the first surface 100a (or the upper surface) of the first substrate 101 throughout the edge region EA may be lower than the vertical level of the first surface 100a (or the upper surface) of the first substrate 101 in the device region CA. As used herein, the term “vertical level”, including for example as shown in FIG. 4 and discussed further herein, “vertical level 1” LV_1 and “vertical level 2” LV_2 may correspond to a vertical distance in the Z direction from the second surface 100b of the first substrate 101 to the respective vertical level.

Referring to FIG. 3B, in a plan view, a first trench TR1 may surround a device region CA of a first substrate 101. In an embodiment, a width W_TR1 of the first trench TR1 may be less than a width W_EA of an edge region EA. The first trench TR1 may be formed in a region of the edge region EA, which is adjacent to the device region CA. In this case, unlike the configuration shown in FIG. 2, the vertical level of the first surface 100a (or the upper surface) of the first substrate 101 in a portion of the edge region EA may be the same as the vertical level of the first surface 100a (or the upper surface) of the first substrate 101 in the device region CA.

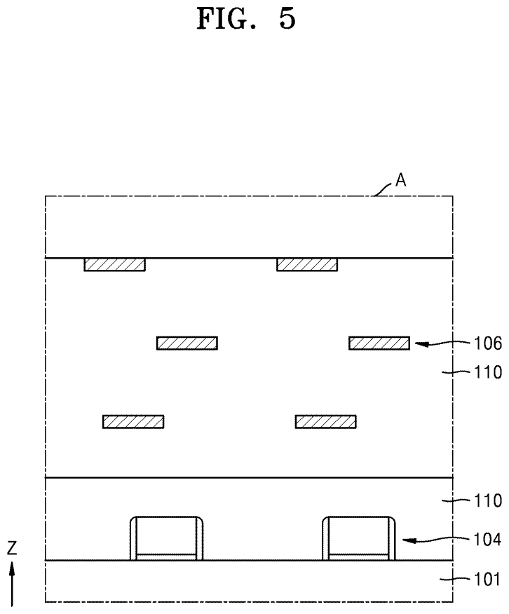

FIG. 4 is a cross-sectional view of a substrate structure in an intermediate stage of processes and illustrates a substrate structure fabricating method, according to an embodiment. FIG. 5 is an enlarged view of region A of FIG. 4.

Referring to FIG. 4, a first insulating layer 110 may be formed on the first surface 100a of the first substrate 101. The first insulating layer 110 may represent an insulating layer for protecting surfaces of device layers, device patterns, wiring patterns, or the like, and may include, for example, a silicon oxide (SiO₂) layer. The first insulating layer may include several interlayer dielectric layers and a final insulating layer (the uppermost/outermost insulating layer that surrounds chip pads, chip pads being used to provide signal and wiring to the integrated circuits of the wafer).

As the first insulating layer 110 is deposited on the first substrate 101, the first insulating layer 110 may include a stepped portion corresponding to the stepped portion of the first substrate 101, for example in the area of the edge region. For example, the first insulating layer 110 may have an insulating layer trench TR1′ that overlaps the first trench TR1. In an embodiment, a vertical level LV_1 of the upper surface of the first insulating layer 110 in the device region CA may be higher than a vertical level LV_2 of the upper surface of the first insulating layer 110 in the edge region EA.

In an embodiment, the first insulating layer 110 may have a constant thickness, including within a stepped portion of the first insulating layer 110. A first thickness D1 of the first insulating layer 110 in the device region CA may be substantially the same as a second thickness D2 of the first insulating layer 110 in the edge region EA.

Referring to FIG. 5, which shows an enlarged view of region A of FIG. 4, a first circuit layer may be located in the device region CA of the first substrate 101. The first circuit layer may include a first device layer 104 and a first wiring pattern 106 and may be understood as a device pattern formed in the device region CA. The first wiring pattern interconnects the first devices (e.g., transistors) to form logic gates and interconnected logic gates form the integrated circuit. The first device layer 104 includes devices/transistors in and/or on the first substrate 101.

The first device layer 104 is illustrated as being formed on the first substrate 101, but the embodiment is not limited thereto. The first device layer 104 may be formed inside the first substrate 101.

The first wiring pattern 106 may be formed above the first device layer 104. The first insulating layer 110 may surround the first device layer 104 and/or the first wiring pattern 106. The first insulating layer 110 may be understood as an insulating layer that surrounds or covers the first circuit layer (or the device pattern) on the first substrate 101. Thus, it should be understood that the first insulating layer 110 need not surround the first device layer 104 on all four sides to be considered “surrounding”.

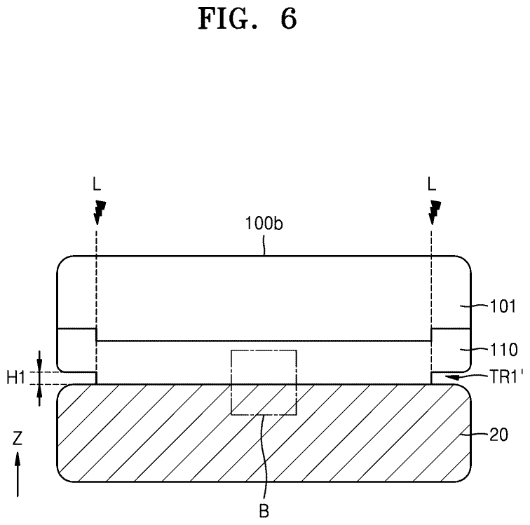

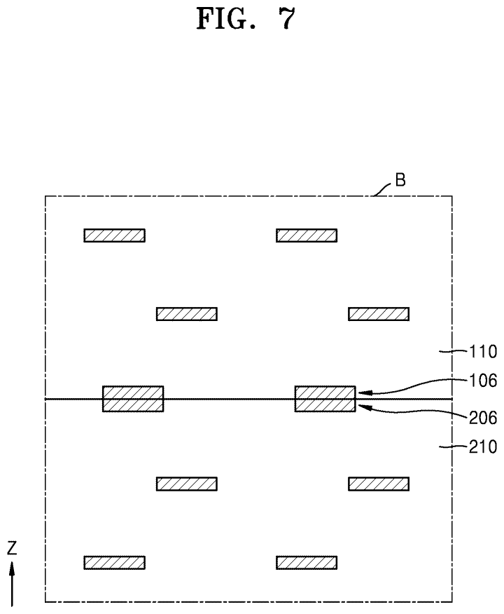

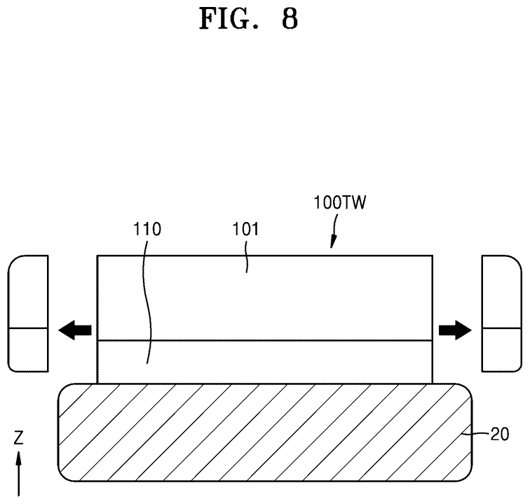

FIGS. 6 and 8 are cross-sectional views of a substrate structure in an intermediate stage of processes and illustrate a substrate structure fabricating method, according to an embodiment. FIG. 7 is an enlarged view of region B of FIG. 6.

Referring to FIG. 6, the first wafer 10 and a second wafer 20 may be bonded to each other. The first wafer 10 may be bonded to the second wafer 20 such that the first insulating layer 110 on the first substrate 101 is adjacent to the second wafer 20. The insulating layer trench TR1′ of the first insulating layer 110 formed by the first trench TR1 of the first substrate 101 may be located between the first substrate 101 and the second wafer 20. Accordingly, in at least a portion of the edge region EA, the first insulating layer 110 may be uniformly spaced apart from the second wafer 20 by the insulating layer trench TR1′.

In the edge region EA, a region in which the first substrate 101 and the first insulating layer 110 are spaced apart from the second wafer 20 is referred to as an un-bonding region. The profile of such an un-bonding region, including for example the shape and/or height (H1) of the un-bonding region in the Z direction, may be adjusted by forming the stepped portion in the upper surface of at least one of the first substrate 101 and the first insulating layer 110 according to various embodiments.

In an embodiment, the second wafer 20 may include a second substrate (or base substrate) and layers formed thereon including for example, a second circuit layer, and a second insulating layer surrounding the second circuit layer. The second circuit layer may include a second device layer and a second wiring pattern. The second device layer includes devices/transistors in and/or on the second substrate (or second base substrate). The second base substrate may include bulk silicon or an SOI. The second base substrate may be a crystalline semiconductor substrate, such as a silicon substrate, or may be formed of one or more other materials, such as, but not limited to, silicon germanium, SGOI, indium antimonide, a lead telluride compound, indium arsenide, indium phosphide, gallium arsenide, or gallium antimonide.

Referring to FIG. 7, the second wafer 20 may include a second insulating layer 210 and a second wiring pattern 206. The second insulating layer 210 may surround the second wiring pattern 206. The second insulating layer may include several interlayer dielectric layers and a final insulating layer (the uppermost/outermost insulating layer that surrounds chip pads, chip pads being used to provide signal and wiring to the integrated circuits of the wafer). In an embodiment, the second wiring pattern 206 in the second wafer 20 may be directly bonded to the first wiring pattern 106 above the first substrate 101. The first wiring pattern 106 may be electrically connected to the second wiring pattern 206. The second wiring pattern 206 interconnects the second devices (e.g., transistors) to form logic gates and interconnected logic gates form the integrated circuit.

As shown in FIG. 7, the first insulating layer 110 is in contact with the second insulating layer 210, and thus, the first wafer 10 may be directly bonded to the second wafer 20 (e.g., via a hybrid bonding process without requiring an additional adhesive layer).

Referring to FIGS. 6 and 8, the second surface 100b of the first substrate 101 may be irradiated with a laser beam L. The laser beam L may create a small vertical gap in the first substrate 101 and/or the first insulating layer 110. For example, the laser beam L may include a laser beam that causes the vertical (e.g., the Z direction) delamination in the first substrate 101 and/or the first insulating layer 110. The edge region EA may be then detached from the device region CA, and thus, a trimmed substrate 100TW attached to the second wafer 20 may be formed.

A cutting process using a laser beam is more precise and efficient than mechanical cutting methods. In particular, the cutting process using a laser beam L is performed in a non-contact manner, which causes little mechanical stress and minimizes damage to a wafer, thereby reducing breakage on the wafer. In the cutting process using a laser beam L, a substrate or the like is irradiated with the laser beam and heated to form a small gap (or a groove), and segments of the substrate may be then separated from each other.

Unlike FIG. 6, in examples when the un-bonding region between the first substrate 101 and the second wafer 20 has an undesirable profile (e.g., there is a region in which the first substrate 101 and the second wafer 20 are in contact with each other in the un-bonding region, or a line from which the un-bonding region starts is not uniform), removal of the edge region EA by using a laser beam may include application of both a laser beam causing delamination in the horizontal direction and a laser beam causing delamination in the vertical direction.

In the substrate structure fabricating method according to various embodiments, the stepped portion may be formed in the first substrate 101 and/or the first insulating layer 110, and thus, the un-bonding region having a uniform profile may be formed, as shown for example in FIG. 6. Accordingly, a process of emitting a laser beam causing the delamination in the horizontal direction may be omitted. For example, the substrate may be trimmed completely and effectively by utilizing the laser beam L that causes the delamination in the vertical direction.

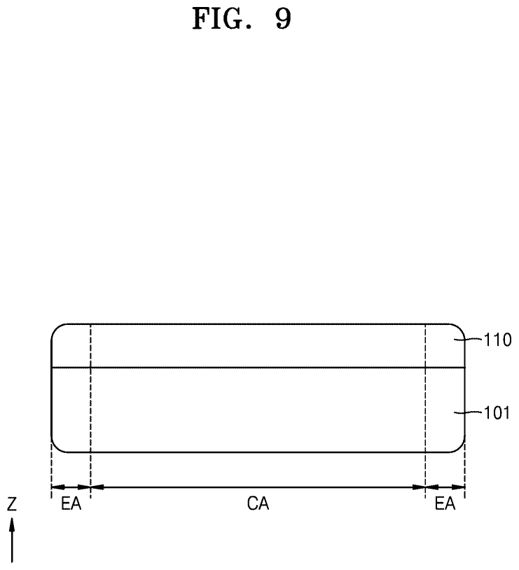

FIGS. 9 to 12 are cross-sectional views of a substrate structure in an intermediate stage of processes and illustrate a substrate structure fabricating method, according to an embodiment. Referring to FIGS. 9 to 12, in a substrate structure fabricating method according to various embodiments, a second trench TR2 may be formed in a first insulating layer 110.

Referring to FIG. 9, in a substrate structure fabricating method according to an embodiment, at first, a first substrate 101 including a device region CA and an edge region EA surrounding the device region CA may be prepared. The first insulating layer 110 may be then formed on the first substrate 101. As described above with reference to FIG. 5, the first insulating layer 110 may surround the first circuit layer (e.g., the first wiring pattern 106).

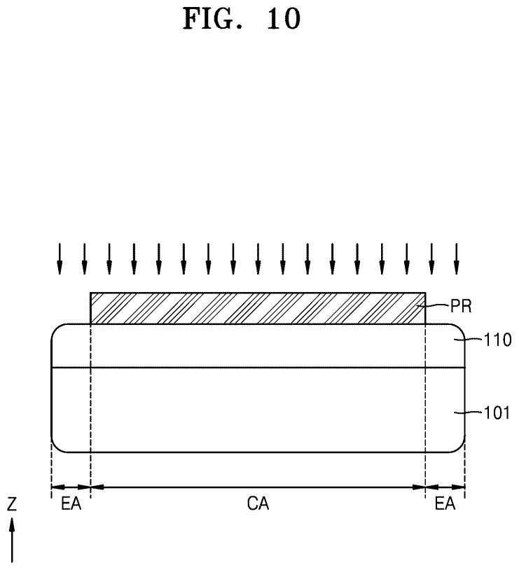

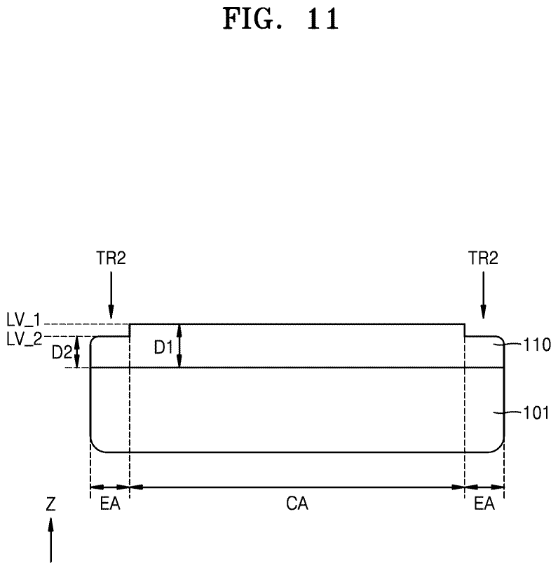

Referring to FIGS. 10 and 11, a stepped portion may be formed in the first insulating layer 110. In an embodiment, the stepped portion of the first insulating layer 110 may be provided by forming a second trench TR2 in the first insulating layer 110. The second trench TR2 may be formed by performing photolithography. First, a photoresist layer PR may be formed on the first insulating layer 110. When the photoresist layer PR includes a positive resist, the photoresist layer PR may overlap the device region CA, as shown in FIG. 10. When the photoresist layer PR includes a negative resist, the photoresist layer PR may overlap the edge region EA. The second trench TR2 of the first insulating layer 110 may be then formed by exposure, development, etching, and photoresist stripping.

Referring to FIG. 11, the second trench TR2 of the first insulating layer 110 may be located in the edge region EA. In an embodiment, the second trench TR2 may surround the device region CA. FIG. 11 illustrates that the width of the second trench TR2 is equal to the width of the edge region EA, but the embodiments are not limited thereto. For example, the width of the second trench TR2 may be less than the width of the edge region EA.

Due to the second trench TR2, a vertical level LV_1 of the upper surface of the first insulating layer 110 in the device region CA may be higher than a vertical level LV_2 of the upper surface of the first insulating layer 110 in the edge region EA. Referring to FIG. 11, unlike FIG. 4, in an embodiment, a first thickness D1 of the first insulating layer 110 in the device region CA may be greater than a second thickness D2 of the first insulating layer 110 in the edge region EA. In an embodiment, the width of the second trench TR2 may be in a range from about 0.5 mm to about 5 mm or about 1 mm to about 4 mm. The width of the second trench TR2 may be about 2 mm.

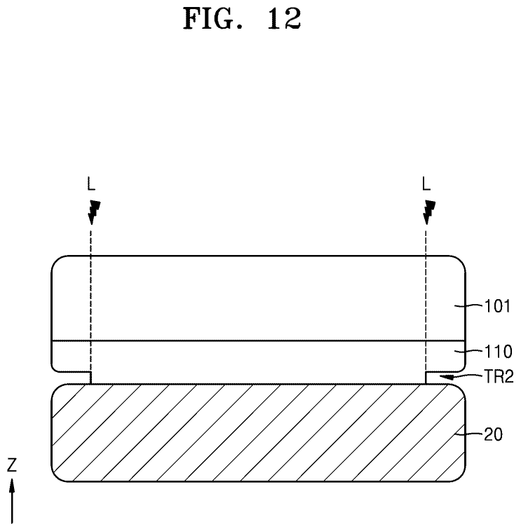

Referring to FIG. 12, the first wafer 10 and a second wafer 20 may be bonded to each other. As described above with reference to FIG. 7, the first wafer 10 may be bonded to the second wafer 20 such that the first insulating layer 110 and a second insulating layer 210 of the second wafer 20 are adjacent to each other. The second trench TR2 of the first insulating layer 110 may be located between the first substrate 101 and the second wafer 20. Accordingly, in at least a portion of the edge region EA, the first insulating layer 110 may be uniformly spaced apart from the second wafer 20. For example, the un-bonding region described above may have a favorable profile.

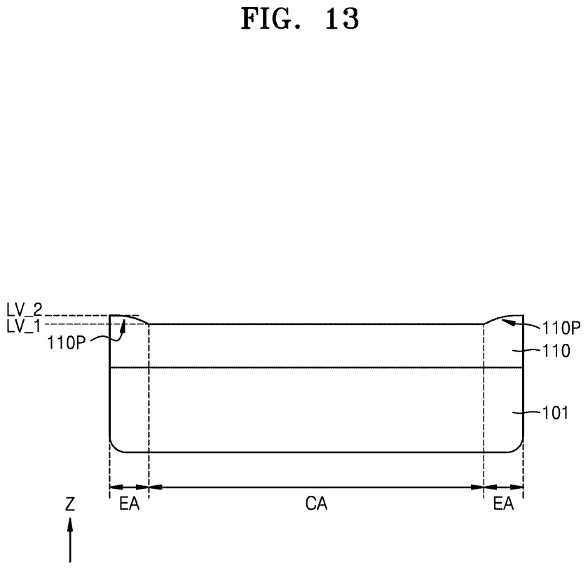

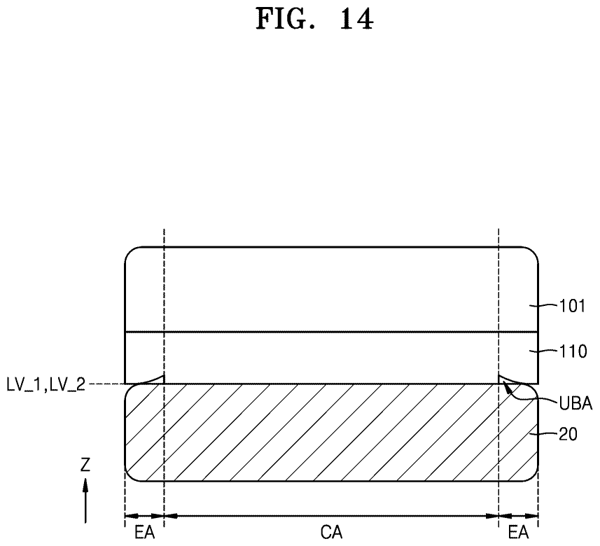

FIGS. 13 and 14 are cross-sectional views of a substrate structure in an intermediate stage of processes and illustrate a substrate structure fabricating method, according to an embodiment.

Referring to FIG. 13, in a substrate structure fabricating method according to an embodiment, at first, a first substrate 101 including a device region CA and an edge region EA surrounding the device region CA may be prepared. A first insulating layer 110 may be then provided on the first substrate 101. The first insulating layer 110 may include a protrusion 110P. The protrusion 110P may overlap the edge region EA. For example, the upper portion of the first insulating layer 110 overlapping the edge region EA may protrude. The protrusion 110P may have a shape that increases in height with distance from the device region CA, as shown in FIG. 13, but various embodiments are not limited thereto. For example, the protrusion 110P may have a peak shape that increases in height and then decreases again, with distance from the device region CA. Alternatively, the protrusion 110P may have a shape that decreases in height with distance from the device region CA. The shape of the protrusion 110P may be changed if necessary.

A material forming the first insulating layer 110 may be uniformly deposited first on the first substrate 101 and then further deposited on the edge region EA, thereby forming the protrusion 110P. In an embodiment, the width of the protrusion 110P in the horizontal direction may be in a range from about 0.5 mm to about 5 mm or about 1 mm to about 4 mm. In an embodiment, the height of the protrusion 110P may be from about 100 angstroms to about 10,000 angstroms or about 1000 angstroms to about 9,000 angstroms.

Referring to FIG. 13, prior to bonding the first wafer 10 to a second wafer 20, a vertical level LV_1 of the upper surface of the first insulating layer 110 in the device region CA (or a vertical level of the protrusion 110P) may be lower than a vertical level LV_2 of the upper surface of the first insulating layer 110 in the edge region EA.

Referring to FIG. 14, which depicts a different type of protrusion than FIG. 13, in which the upper portion of the protrusion 110P is the same height as the upper portion of the first insulating layer 110, in contrast to FIG. 13, in which the lower portion of the protrusion 110P is the same height as the upper portion of the first insulating layer 110, the first wafer 10 and the second wafer 20 may be bonded to each other. As described above with reference to FIG. 7, the first wafer 10 may be bonded to the second wafer 20 such that the first insulating layer 110 and a second insulating layer 210 of the second wafer 20 are adjacent to each other. A bonding portion of the first insulating layer 110 may be located between the first substrate 101 and the second wafer 20.

When bonding the first wafer 10 to the second wafer 20, bonding strength may decrease toward the edge region EA. Accordingly, in the device region CA in which the bonding strength is sufficient, the first wafer 10 and the second wafer 20 are bonded to each other without voids, but in the edge region EA, an un-bonding region UBA having a favorable profile may be defined due to the protrusion 110P of the first insulating layer 110. The desired profile of the un-bonding region UBA may be obtained by adjusting the shape, width, thickness, or the like of the protrusion 110P in the first insulating layer 110.

Referring to FIG. 14, after bonding the first wafer 10 to the second wafer 20, the vertical level LV_2 of the upper surface of the first insulating layer 110 in the edge region EA may be higher than or equal to the vertical level LV_1 of the upper surface of the first insulating layer 110 in the device region CA (or the vertical level of the protrusion 110P). Here, the vertical level LV_1 of the upper surface of the first insulating layer 110 in the device region CA (or the vertical level of the protrusion 110P) does not only represent the vertical level of the highest point of the protrusion 110P, but may represent the vertical level at each point on the upper surface of the first insulating layer 110.

Subsequently, a laser beam causing delamination in the vertical direction may be emitted to a first surface of the first substrate 101, and the edge region EA may be separated from the device region CA.

In the substrate structure fabricating method according to various embodiments described with reference to FIGS. 1 to 14, a first substrate including an edge region and a device region may be prepared, a first insulating layer may be formed on the first substrate, the first wafer 10 and the second wafer 20 may be bonded to each other, and a laser beam L may be emitted onto the first wafer 10. The laser beam may include a laser beam that causes delamination of the first wafer in the vertical direction (e.g. a Z direction). In an embodiment, the first insulating layer 110 may have a stepped portion. In an embodiment, a first trench TR1 may be formed in the first substrate 101 and then the first insulating layer 110 may be formed on the first substrate 101. Accordingly, the first insulating layer 110 may have a stepped portion. In an embodiment, a second trench TR2 may be formed in the first insulating layer 110, and thus, the first insulating layer 110 may have a stepped portion. In an embodiment, a protrusion 110P may be formed in the first insulating layer 110, and thus, the first insulating layer 110 may have a stepped portion. By these stepped portions, the profile of the un-bonding region between the first wafer 10 and the second wafer 20 may be adjusted artificially. Furthermore, when trimming a substrate with a laser beam, a laser process operation for delamination of the substrate in the horizontal direction may be omitted.

While the inventive concept has been particularly shown and described with reference to embodiments thereof, it will be understood that various changes in form and details may be made therein without departing from the spirit and scope of the following claims.

What is claimed is:

1. A method of manufacturing comprising:
preparing a first substrate comprising a first surface and a second surface opposite the first surface, wherein the first substrate comprises a device region and an edge region surrounding the device region;
forming a first insulating layer on the first surface of the first substrate, the first insulating layer having a lower surface adjacent to the first surface of the first substrate, and an upper surface opposite the lower surface, the first substrate and the first insulating layer forming a first wafer;
forming a stepped portion in the upper surface of the first insulating layer so that a first vertical level of a first portion of the upper surface of the first insulating layer in the device region is different from a second vertical level of a second portion of the upper surface of the first insulating layer in the edge region;
bonding the first wafer to a second wafer; and
separating the edge region from the device region of the first substrate by emitting a laser beam onto the second surface of the first substrate.

2. The method of claim 1, wherein the laser beam causes delamination of the first wafer in a vertical direction.

3. The method of claim 1, wherein, after the first wafer is bonded to the second wafer, the first wafer and the second wafer are spaced apart from each other at least partially in the edge region.

4. The method of claim 1, wherein the first vertical level of the first portion of the upper surface of the first insulating layer in the device region is higher than the second vertical level of the second portion of the upper surface of the first insulating layer in the edge region.

5. The method of claim 4, wherein the forming of the stepped portion in the upper surface of the first insulating layer comprises forming a first trench surrounding the device region, in the edge region of the first substrate, prior to forming the first insulating layer.

6. The method of claim 4, wherein the forming of the stepped portion comprises performing photolithography to form a second trench surrounding the device region, in the first insulating layer.

7. The method of claim 6, wherein, performing photolithography comprises first forming a photoresist layer overlapping at least one of the device region or the edge region on the first insulating layer.

8. The method of claim 1, wherein the forming of the stepped portion in the upper surface of the first insulating layer comprises protruding an upper portion of the upper surface of the first insulating layer in the edge region.

9. The method of claim 8, wherein, prior to bonding the first wafer to the second wafer, the first vertical level of the upper surface of the first insulating layer in the device region is lower than the second vertical level of the upper surface of the first insulating layer in the edge region.

10. The method of claim 8, wherein, after bonding the first wafer to the second wafer, the first vertical level of the upper surface of the first insulating layer in the device region is higher than or equal to the second vertical level of the upper surface of the first insulating layer in the edge region.

11. The method of claim 1, wherein a width of the edge region is in a range from 0.5 mm to 5 mm.

12. A method of manufacturing comprising:
preparing a first substrate comprising a first surface and a second surface opposite the first surface, wherein the first substrate comprises a device region and an edge region surrounding the device region;
forming a first trench surrounding the device region, in the first surface of the first substrate;
forming a first circuit layer and a first insulating layer surrounding the first circuit layer, on the first substrate in which the first trench is formed, the first substrate and the first insulating layer forming a first wafer;
bonding the first wafer to a second wafer so that the first insulating layer and a second insulating layer of the second wafer are adjacent to each other; and
separating the edge region from the device region of the first substrate by emitting a laser beam onto the second surface of the first substrate.

13. The method of claim 12, wherein a first thickness of the first insulating layer in the device region is equal to a second thickness of the first insulating layer in the edge region.

14. The method of claim 12, wherein a first vertical level of an upper surface of the first insulating layer in the device region is higher than a second vertical level of an upper surface of the first insulating layer in the edge region.

15. The method of claim 12, wherein a width of the first trench is less than a width of the edge region.

16. The method of claim 12, wherein a width of the first trench is in a range from 0.5 mm to 5 mm.

17. A method of manufacturing comprising:
preparing a first substrate comprising a first surface and a second surface opposite the first surface, wherein the first substrate comprises a device region and an edge region surrounding the device region;
forming a first circuit layer and a first insulating layer surrounding the first circuit layer, on the first substrate; the first insulating layer having a lower surface adjacent to the first surface of the first substrate, and an upper surface opposite the lower surface, the first substrate and the first insulating layer forming a first wafer;
forming a stepped portion in the upper surface of the first insulating layer;
bonding the first wafer to a second wafer so that the first insulating layer and a second insulating layer of the second wafer are adjacent to each other; and
separating the edge region from the device region of the first substrate by emitting a laser beam onto the second surface of the first substrate.

18. The method of claim 17, wherein the forming of the stepped portion comprises performing photolithography to form a second trench surrounding the device region, in the first insulating layer.

19. The method of claim 18, wherein a width of the second trench is in a range from 0.5 mm to 5 mm.

20. The method of claim 17, wherein the forming of the stepped portion in the upper surface of the first insulating layer comprises protruding an upper portion of the upper surface of the first insulating layer in the edge region.
